(19) United States
(12) Patent Application Publication
(10) Pub. No.: US 2014/0376659 A1
(43) Pub. Date: Dec. 25, 2014

(54) TRANSMISSION APPARATUS AND HIGH FREQUENCY FILTER

(71) Applicant: FUJITSU LIMITED, Kawasaki-shi (JP)

(72) Inventor: Masami Saito, Yokohama (JP)

(73) Assignee: FUJITSU LIMITED, Kawasaki-shi (JP)

(21) Appl. No.: 14/263,182

(22) Filed: Apr. 28, 2014

(30) Foreign Application Priority Data
Jun. 24, 2013 (JP) 2013-131989

(51) Int. Cl. H03H 7/01; H03H 7/38; H04B 1/04

(52) U.S. Cl. CPC H03H 7/01; H04B 1/0475; H03H 7/38
USPC 375/296; 333/33; 333/35

(57) ABSTRACT

An apparatus includes: a transmission circuit configured to output a differential signal; a first filter configured to filter the differential signal; a differential line that is configured to transmit the differential signal filtered and has an electrical length of m·λ/2 (m: a positive integer); a second filter configured to filter the differential signal transmitted on the differential line; and a reception circuit to which the differential signal filtered by the second filter is input, wherein the first filter and the second filter are each constituted by a reactance element, and wherein impedance matching is implemented regarding a differential component of the differential signal at a frequency times as high as the basis frequency, and impedance mismatching is caused regarding a differential component of the differential signal at a frequency other than the frequency times as high as the basis frequency and a common-mode component of the differential signal.

### CROSS-REFERENCE TO RELATED APPLICATION

This application is based upon and claims the benefit of priority from the prior Japanese Patent Application No. 2013-131989 filed on Jun. 24, 2013, the entire contents of which are incorporated herein by reference.

### FIELD

The embodiments discussed herein are related to a transmission apparatus and a high frequency filter.

### BACKGROUND

A logical circuit including a central processing unit (CPU) or the like is operated while a clock signal is set as a reference and receives a supply of clock signals. The clock signals are generated by an oscillation circuit or the like and supplied to respective units via a transmission apparatus (transmission circuit). Herein, a differential clock signal is used as an intended clock signal. The differential clock signal is a differential rectangular-wave signal.

A balanced transmission apparatus for the differential clock signal includes a differential clock transmitter, a differential clock receiver, and a differential line. The differential clock transmitter is, for example, an IC chip that generates a differential clock signal. The differential clock receiver is, for example, a CPU. The differential line is a line that connects between the differential clock transmitter and the differential clock receiver. For example, the differential line is a line on a printed circuit board or a line within an IC. The differential line is constituted by two lines. Line widths of the two lines are adjusted to have a desirable characteristic impedance (for example, 50 n), and the lengths of the two lines are equal to each other.

The differential clock signal is transmitted from the differential clock transmitter to the differential clock receiver via the differential line. The differential clock signal transmitted from the differential clock transmitter includes a positive signal and a negative signal where phases are inverted by 180°. A differential component of the differential clock signal is a difference of the positive signal and the negative signal, and it is ideal that a common-mode component of the positive signal and the negative signal is zero.

However, in an actual transmission of the differential clock signal, noise other than the ideal signal component is generated and becomes a cause of jitter or crosstalk. The noise also becomes a cause for imparting an influence on other signal transmissions.

One of measures for reducing the noise in the transmission of the differential clock signal is to use a chip common-mode choke coil. However, differential noise is not reduced by using the chip common-mode choke coil, and a high frequency signal is not dealt with.

Another one of the measures for reducing the noise in the transmission of the differential clock signal is to use a filter using a reactance element that functions as a sine-wave differential filter. However, with the filter using the reactance element described in Japanese Patent No. 4339838, a resonance point is generated in a common-mode filter characteristic. Since the filter using the reactance element is a narrow-band filter, noise is generated in a broad band region in a differential rectangular signal like the differential clock signal, and the noise is not entirely removed.

See, for example, Japanese Laid-open Patent Publication No. 2006-129131 and Japanese Laid-open Patent Publication No. 11-17405.

### SUMMARY

According to an aspect of the invention, a transmission apparatus include: a transmission circuit configured to output a differential signal; a first filter configured to filter the differential signal output by the transmission circuit; a differential line that is configured to transmit the differential signal filtered by the first filter and has a length of m λ/2 (m: a positive integer, λ: an electrical length corresponding to a basis frequency of the differential signal); a second filter configured to filter the differential signal transmitted on the differential line; and a reception circuit to which the differential signal filtered by the second filter is input, wherein the first filter and the second filter are each constituted by a reactance element, and wherein impedance matching is implemented with respect to a differential component of the differential signal at a frequency (2n−1) (n: a positive integer) times as high as the basis frequency, and impedance mismatching is caused with respect to a differential component of the differential signal at a frequency other than the frequency (2n−1) (n: a positive integer) times as high as the basis frequency and a common-mode component of the differential signal.

The object and advantages of the invention will be implemented and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 illustrates a configuration of a general balanced transmission apparatus for a differential clock signal;

FIGS. 2A and 2B illustrate the differential clock signal transmitted from a differential clock transmitter, in which FIG. 2A illustrates the differential clock signal and

FIG. 2B illustrates a differential component and a common-mode component of the differential clock signal;

FIGS. 3A, 3B, and 3C illustrate an ideal differential clock signal received by a differential clock receiver, in which FIG. 3A illustrates the ideal differential clock signal, FIG. 3B illustrates a differential component and a common-mode component of the ideal differential clock signal, and FIG. 3C illustrates frequency components of the differential component and the common-mode component;

FIG. 4 is an explanatory diagram for explaining locations where noise is generated in a transmission of the differential clock signal;

FIGS. 5A and 5B are explanatory diagrams for explaining noise generated by a shift of a transmitted positive signal and a transmitted negative signal, in which FIG. 5A illustrates the positive signal and the negative signal which are shifted, and FIG. 5B illustrates the noise generated in the differential component and the common-mode component;

FIGS. 6A and 6B illustrate a balanced transmission apparatus for the differential clock signal using a chip common-mode choke coil, in which FIG. 6A illustrates a circuit configuration, and FIG. 6B illustrates a filter characteristic (frequency characteristic) of the chip common-mode choke coil;

FIGS. 7A, 7B, and 7C illustrate a case in which a differential filter using a reactance element is used in the balanced transmission apparatus for the differential clock signal illustrated in FIG. 1, in which FIG. 7A illustrates a circuit configuration, FIG. 7B illustrates a configuration example of the differential filter, and FIG. 7C illustrates a filter characteristic (frequency characteristic);

FIGS. 8A, 8B, 8C, and 8D illustrate a balanced transmission apparatus for the differential clock signal according to a first embodiment;

FIGS. 9A and 9B illustrate frequency characteristics of a short stub and a shunt line of a filter used according to the first embodiment, in which FIG. 9A illustrates the frequency characteristic of the short stub, and FIG. 9B illustrates the frequency characteristic of the shunt line;

FIGS. 10A and 10B illustrate an equivalent circuit of the common-mode component in the filter illustrated in FIG. 7B and a Smith chart representing a phase relationship, in which FIG. 10A illustrates the equivalent circuit, and FIG. 10B illustrates the Smith chart;

FIGS. 11A and 11B illustrate an equivalent circuit of the common-mode component in the filters according to the first embodiment illustrated in FIG. 8B and a Smith chart representing a phase relationship, in which FIG. 11A illustrates the equivalent circuit, and FIG. 11B illustrates the Smith chart;

FIGS. 12A and 12B illustrate an equivalent circuit of the differential component in the filter illustrated in FIG. 7B and a Smith chart representing a phase relationship, in which FIG. 12A illustrates the equivalent circuit, and FIG. 12B illustrates the Smith chart;

FIGS. 13A and 13B illustrate an equivalent circuit of the differential component in the filters according to the first embodiment illustrated in FIG. 8B and a Smith chart representing a phase relationship, in which FIG. 13A illustrates the equivalent circuit, and FIG. 13B illustrates the Smith chart;

FIGS. 14A and 14B illustrate a circuit configuration of filters used in a balanced transmission apparatus for the differential clock signal according to a second embodiment and a frequency characteristic of the balanced transmission apparatus, in which FIG. 14A illustrates the circuit configuration, and FIG. 14B illustrates the frequency characteristic of the balanced transmission apparatus;

FIGS. 15A and 15B illustrate a configuration in a case where a differential line and filters before and after the differential line in the balanced transmission apparatus according to the second embodiment are implemented by a balanced strip line formed on a dielectric substrate, in which FIG. 15A illustrates a line pattern and FIG. 15B is a cross sectional view of the line;

FIGS. 16A and 16B illustrate a circuit configuration of filters used in a balanced transmission apparatus for the differential clock signal according to a third embodiment and a frequency characteristic of the balanced transmission apparatus, in which FIG. 16A illustrates the circuit configuration, and FIG. 16B illustrates the frequency characteristic of the balanced transmission apparatus; and

FIGS. 17A, 17B and 17C illustrate circuit configurations of a filter used in a balanced transmission apparatus for the differential clock signal according to a fourth embodiment and a frequency characteristic of the balanced transmission apparatus, in which FIGS. 17A and 17B illustrate the circuit configurations and FIG. 17C illustrates the frequency characteristic of the balanced transmission apparatus.

### DESCRIPTION OF EMBODIMENTS

A general balanced transmission apparatus for a differential clock signal will be described with reference to the drawings before a description of embodiments will be given.

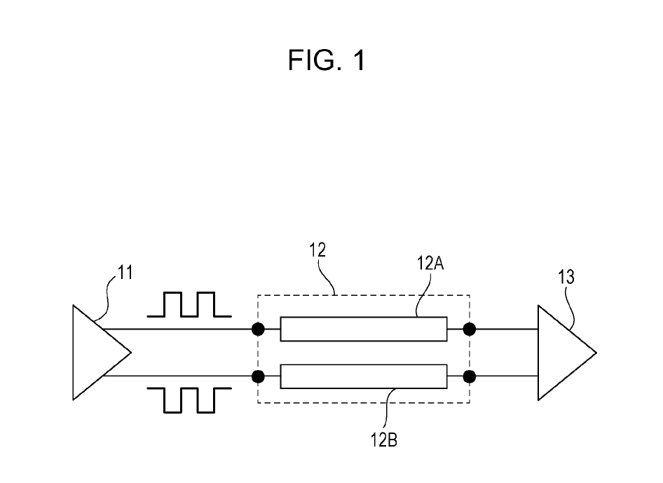

FIG. 1 illustrates a configuration of the general balanced transmission apparatus for the differential clock signal.

The balanced transmission apparatus includes a differential clock transmitter (circuit) 11, a differential line 12, and a differential clock receiver (circuit) 13. The differential clock transmitter 11 is, for example, an IC chip that generates differential clock signal. The differential clock receiver 13 is, for example, a CPU or the like that operates based on the differential clock signal. The differential line 12 includes two lines 12A and 12B that connect two outputs of the differential clock transmitter 11 to two inputs of the differential clock receiver 13. Line widths of the two lines 12A and 12B are adjusted to have a desirable characteristic impedance (for example, 50Ω). Lengths of the two lines 12A and 12B are equal to each other. The differential clock signal generated by the differential clock transmitter 11 is a differential rectangular wave and is transmitted towards the differential clock receiver 13 via the differential line 12. In the following explanation, a differential clock signal at 0.1 GHz will be taken as an example.

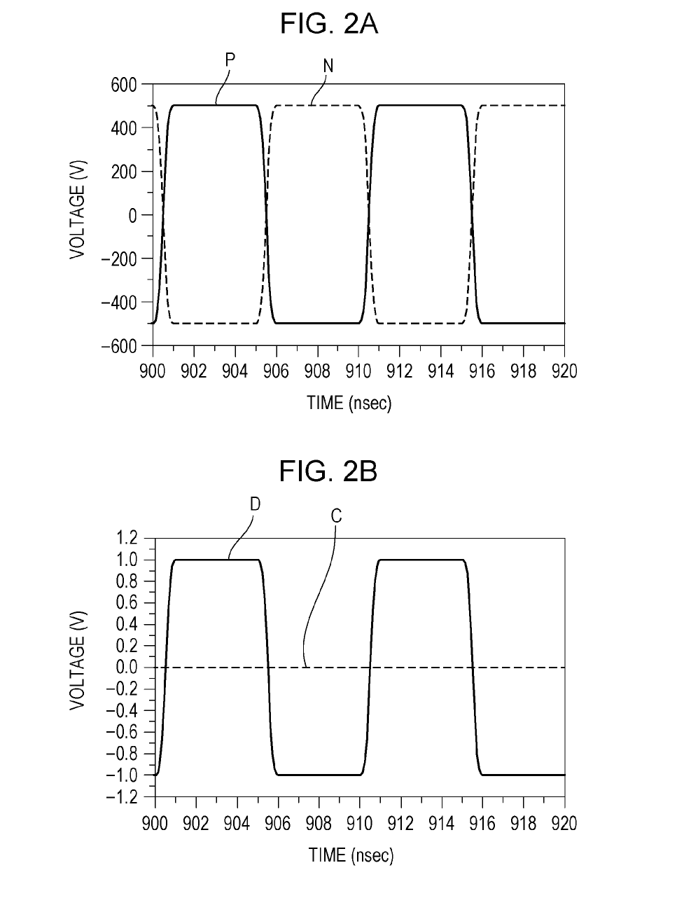

FIGS. 2A and 2B illustrate the differential clock signal transmitted from the differential clock transmitter 11, in which FIG. 2A illustrates the differential clock signal and FIG. 2B illustrates a differential component and a common-mode component of the differential clock signal.

As illustrated in FIG. 2A, the differential clock signal includes a positive signal P and a negative signal N where phases are inverted by 180°. In other words, the positive signal P and the negative signal N are symmetric signals with respect to a center level.

A difference between the positive signal P and the negative signal N corresponds to a differential component D, and a signal obtained by adding the positive signal P to the negative signal N and then dividing the resultant by 2 corresponds to a common-mode component C as illustrated in FIG. 2B. In the transmission of the differential clock signal, only the differential component D is created, and the common-mode component C is not created. In other words, the common-mode component C is ideally zero.

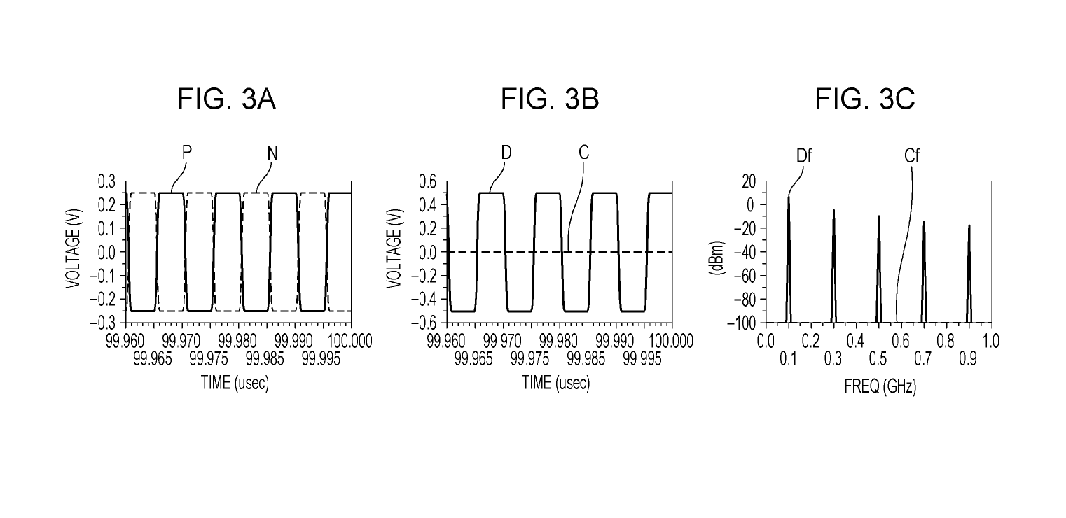

FIGS. 3A, 3B, and 3C illustrate an ideal differential clock signal received by the differential clock receiver 13, in which FIG. 3A illustrates the ideal differential clock signal, FIG. 3B illustrates a differential component and a common-mode component of the ideal differential clock signal, and FIG. 3C illustrates frequency components of the differential component and the common-mode component.

As illustrated in FIG. 3A, the ideal differential clock signal includes the positive signal P and the negative signal N where phases are inverted by 180°, and the positive signal P and the negative signal N are symmetric signals with respect to the center level.

As illustrated in FIG. 3B, the differential component D of the ideal differential clock signal is a signal alike to a rectangular wave symmetric with respect to the center level, and the common-mode component C is a signal at zero (fixed at the center level).

As illustrated in FIG. 3C, when a basic frequency (clock frequency) of the differential clock signal is set as f0, the frequency component of the differential component D of the ideal differential clock signal has components in vicinity of frequencies f0, 3f0, and 5f0 that are (2n−1) (n: a positive integer) times as high as f0. The common-mode component C is zero across all the frequencies.

However, in an actual transmission of the differential clock signal, noise other than the ideal signal component is generated and becomes a cause of jitter or crosstalk.

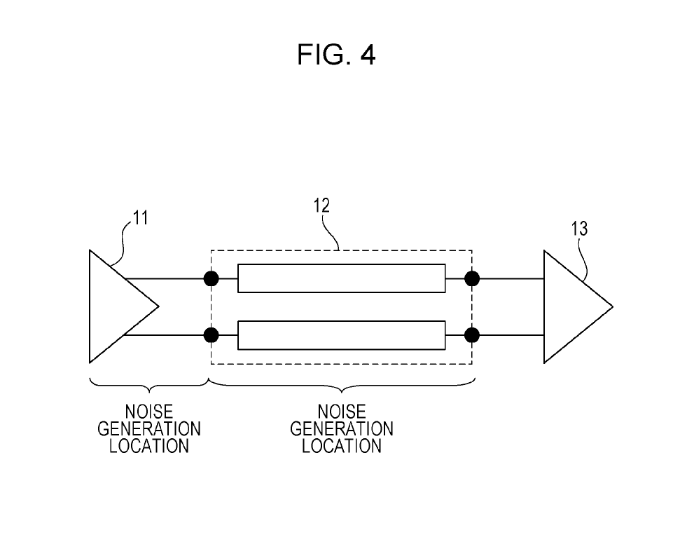

FIG. 4 is an explanatory diagram for explaining locations where noise is generated in the transmission of the differential clock signal.

As illustrated in FIG. 4, the noise is generated in the differential clock transmitter 11, a section from output terminals of the differential clock transmitter 11 to input terminals of the differential line 12, and the differential line 12 with respect to the transmitted differential clock signal. A shift of the timings for the positive signal and the negative signal or the like becomes a cause of the noise. The differential clock receiver 13 receives the differential clock signal on which the noise is superposed and reproduces the differential clock signal to be output. In a case where another signal line is provided in parallel with the differential line 12, the noise is also a cause of imparting an influence on the other signal.

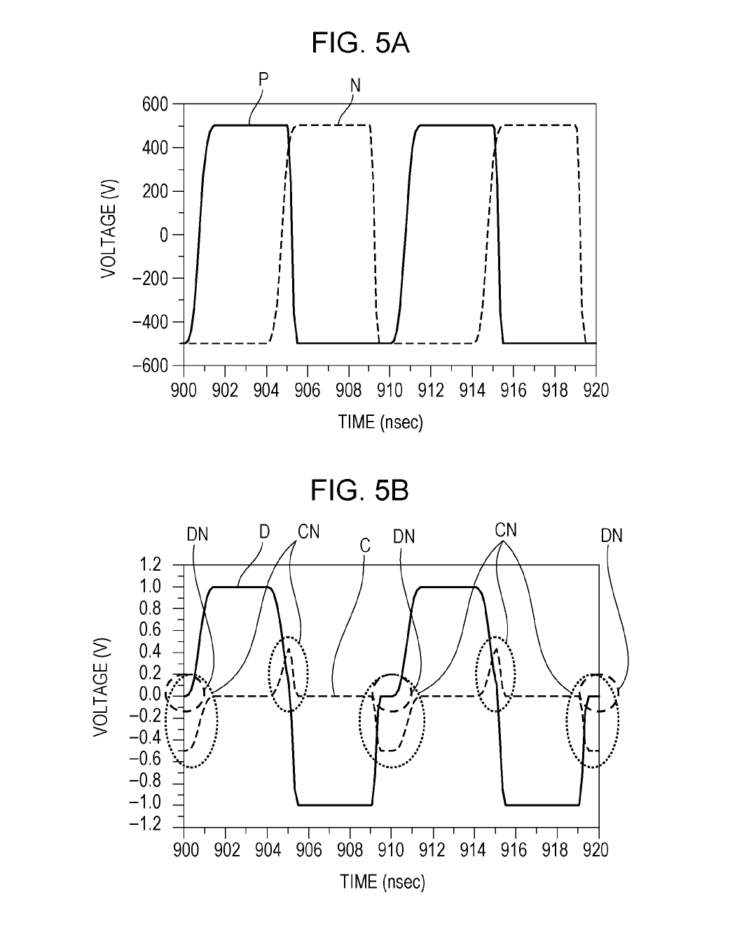

FIGS. 5A and 5B are explanatory diagrams for explaining noise generated by a shift of the transmitted positive signal P and the transmitted negative signal N, in which FIG. 5A illustrates the positive signal P and the negative signal N which are shifted, and FIG. 5B illustrates noise generated in the differential component and the common-mode component.

According to an example illustrated in FIG. 5A, the positive signal P is delayed with respect to the negative signal N, and a shift is caused. When the shift as illustrated in FIG. 5A is caused, the noise is generated in parts denoted by DN in the differential component D as illustrated in FIG. 5B, and the noise is generated in parts denoted by CN in the common-mode component C. When such noise is generated, jitter is generated in the reproduced differential clock signal. When external noise is received in the differential line 12, jitter is similarly generated in the reproduced differential clock signal.

To reduce the noise in the transmission of the differential signal, the chip common-mode choke coil is used.

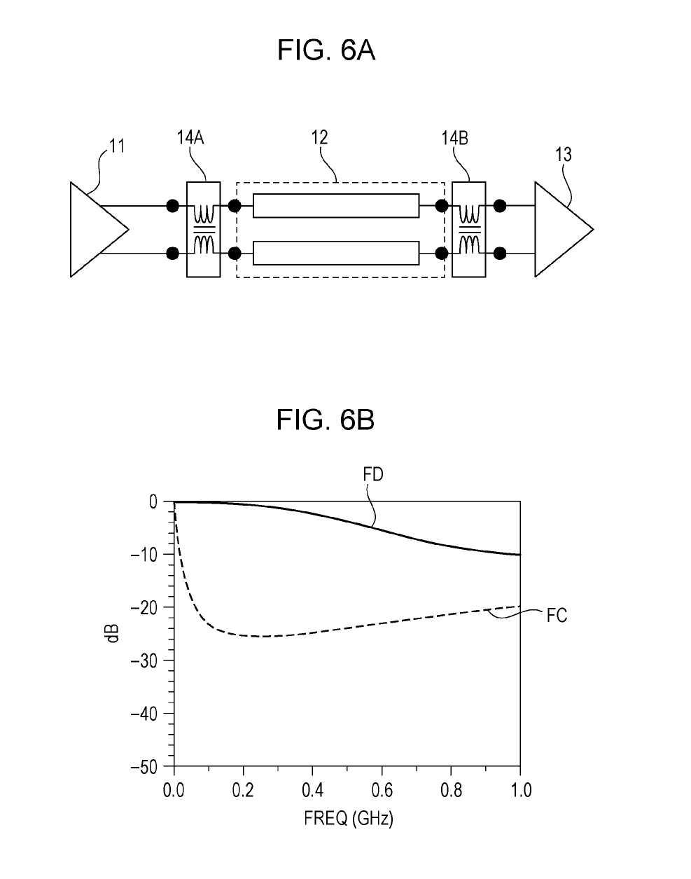

FIGS. 6A and 6B illustrate the balanced transmission apparatus for the differential clock signal using the chip common-mode choke coil, in which FIG. 6A illustrates a circuit configuration, and FIG. 6B illustrates a filter characteristic (frequency characteristic) of the chip common-mode choke coil.

As illustrated in FIG. 6A, the chip common-mode choke coil 14A is connected between the differential clock transmitter 11 and the differential line 12, and the chip common-mode choke coil 14B is connected between the differential line 12 and the differential clock receiver 13.

In FIG. 6B, FD denotes a filter characteristic of the chip common-mode choke coil with respect to the differential component, and FC denotes a filter characteristic of the chip common-mode choke coil with respect to the common-mode component. From FIG. 6B, the chip common-mode choke coil transmits the differential component without much attenuation but causes the common-mode component to attenuate. Therefore, since the chip common-mode choke coil is provided as illustrated in FIG. 6A, the noise of the common-mode component can be reduced, but the noise of the differential component is not reduced. An effect of the chip common-mode choke coil is not sufficient for the differential clock signal at a high frequency (for example, 1 GHz or higher).

Japanese Patent No. 4339838 describes a differential filter for a sign-wave signal using a reactance element.

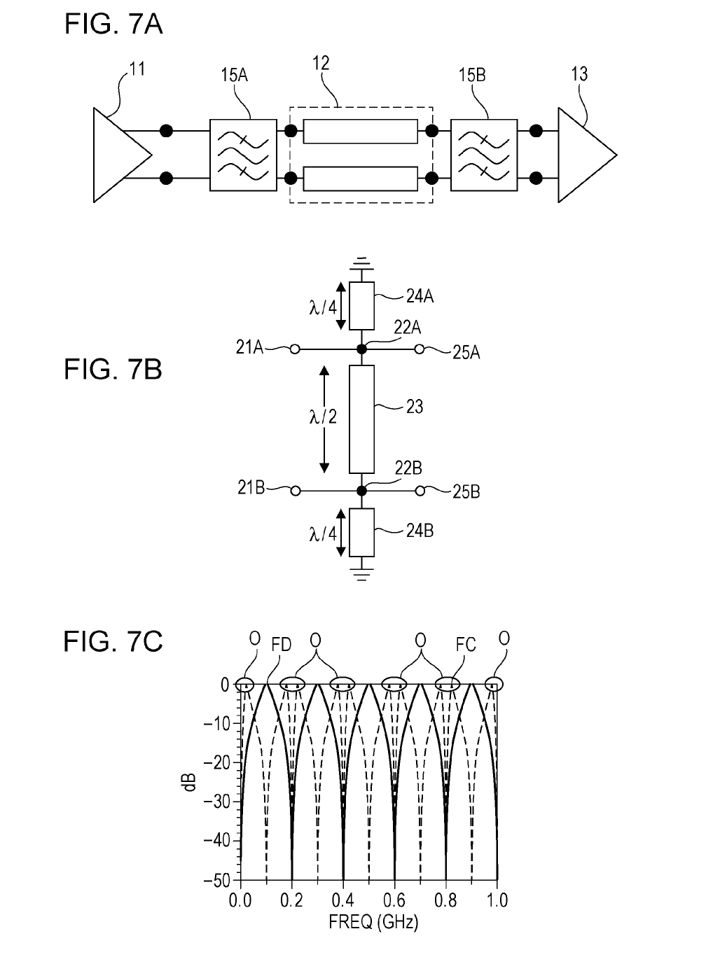

FIGS. 7A, 7B, and 7C illustrate a case in which the differential filter using the reactance element is used in the balanced transmission apparatus for the differential clock signal illustrated in FIG. 1, in which FIG. 7A illustrates a circuit configuration, FIG. 7B illustrates a configuration example of the differential filter, and FIG. 7C illustrates a filter characteristic (frequency characteristic).

As illustrated in FIG. 7A, a differential filter 15A is connected between the differential clock transmitter 11 and the differential line 12, and a differential filter 15B is connected between the differential line 12 and the differential clock receiver 13.

As illustrated in FIG. 7B, the differential filters 15A and 15B include a positive input terminal 21A, a λ/2 electrical length line 23, and two λ/4 electrical length lines 24A and 24B. The λ/2 electrical length line 23 is a line having a λ/2 electrical length which is connected between a connection node 22A on a route between the positive input terminal 21A and a positive output terminal 25A and a connection node 22B on a route between a negative input terminal 21B and a negative output terminal 25B. The λ/4 electrical length line 24A is a line having a λ/4 electrical length which is connected between the connection node 22A and a ground terminal. The λ/4 electrical length line 24B is a line having a λ/4 electrical length which is connected between the connection node 22B and the ground terminal. The λ/2 electrical length and the λ/4 electrical length line are implemented by a capacitance, an inductor, a line, or the like and represented in a format of an electrical length line in the following explanation. With regard to details of the electrical length, see http://en.wikipedia.org/wiki/Electrical_length, for example. The electrical length is set as a reference for all λ used in the following explanation.

In FIG. 7C, FD denotes filter characteristics of the differential filters 15A and 15B with respect to the differential component, FC denotes filter characteristics of the differential filters 15A and 15B with respect to the common-mode component, and O denotes a resonance point of the common-mode component. As illustrated in FIG. 7C, the differential filters 15A and 15B using the reactance element are narrow band filters since the resonance points O are generated in the filter characteristic of the common-mode component. The differential rectangular signal like the differential clock signal generates the noise in a broad band region, so that not all the noise is removed by the differential filters 15A and 15B described above.

Next, a balanced transmission apparatus for the differential clock signal according to an embodiment will be described.

As described above, the ideal differential clock signal includes the differential component (2n−1) times as high as the basis frequency f0 but does not include the common-mode component. According to an embodiment, the differential filter provided on the differential line is constituted by the reactance element, impedance matching is implemented at the frequency (2n−1) (n: a positive integer) times as high as f0, and impedance mismatching is caused at the frequency other than the frequency (2n−1) times as high as f0. According to this, a reflection occurs in components other than the common-mode component and the differential components (2n−1) times as high as the basis frequency f0, and the common-mode noise and the differential noise are reduced. Furthermore, the resonance point is not generated in the common-mode component of the filter.

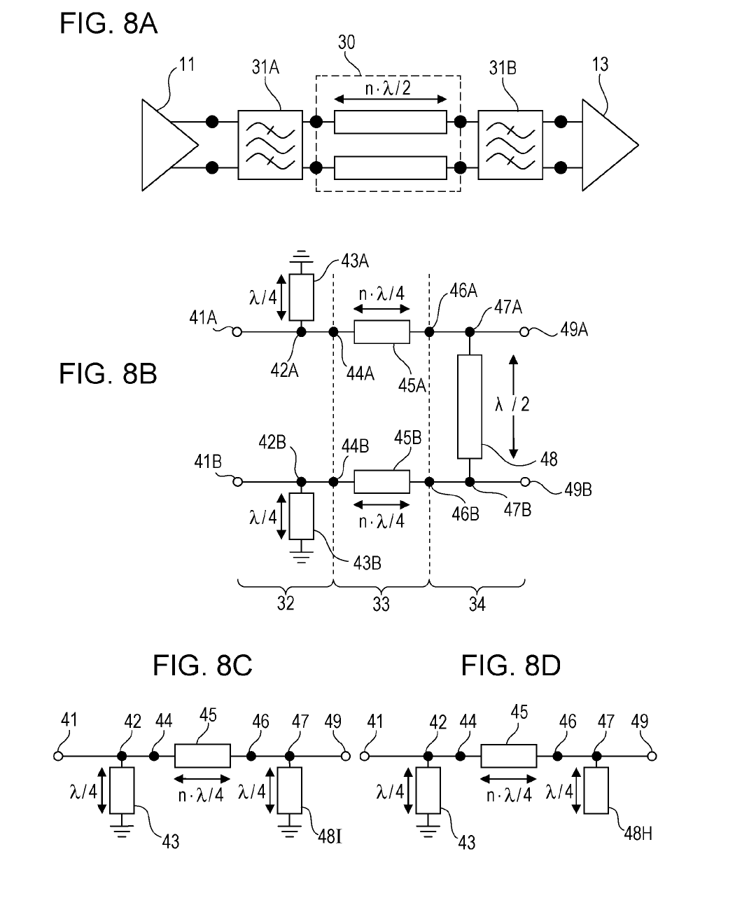

FIGS. 8A, 8B, 8C, and 8D illustrate a balanced transmission apparatus for the differential clock signal according to a first embodiment. FIG. 8A illustrates a circuit configuration. FIG. 8B illustrates a filter configuration used according to the first embodiment. FIG. 8C illustrates an equivalent circuit of the differential component in the filter. FIG. 8D illustrates an equivalent circuit of the common-mode component in the filter.

As illustrated in FIG. 8A, the balanced transmission apparatus according to the first embodiment includes the differential clock transmitter (circuit) 11, a differential line 30, the differential clock receiver (circuit) 13, a filter 31A, and a filter 31B. As described above, the differential clock transmitter 11 is, for example, an IC chip configured to generate the differential clock signal. The differential clock receiver 13 is, for example, a CPU or the like that operates based on the differential clock signal. The differential clock signal generated by the differential clock transmitter 11 is a differential rectangular wave and is transmitted towards the differential clock receiver 13 via the filter 31A, the differential line 30, and the filter 31B.

The differential line 30 includes two lines that connect the two outputs of the differential clock transmitter 11 with the two inputs of the differential clock receiver 13. The two lines 12A and 12B are lines formed on a dielectric substrate. The line widths of the two lines 12A and 12B are adjusted to have a desirable characteristic impedance (for example, 50Ω). The lengths of the two lines 12A and 12B are equal to each other. The lengths of the two lines 12A and 12B are set as n/2 (n: a positive integer) of λ corresponding to the frequency f0 of the differential clock signal to be transmitted.

The filter 31A reduces noise of the differential clock signal output by the differential clock transmitter 11. The filter 31B reduces noise of the differential clock signal transmitted via the differential line 30. Herein, the noise refers to a component of the transmitted differential clock signal having a rectangular wave shape, that is, a component other than the component at the frequency (2n−1) (n: a positive integer) times as high as the frequency f0 of the differential clock signal.

As illustrated in FIG. 8B, the filters 31A and 31B include a short stub 32, an n·λ/4 line 33, and a shunt line 34 corresponding to three types of the reactance elements. The short stub 32 includes a λ/4 line 43A connected between a connection node 42A and the ground terminal on a line connected to a positive input terminal 41A and a λ/4 line 43B connected between a connection node 42B and the ground terminal on a line connected to a negative input terminal 41B.

The n·λ/4 line 33 is connected to the short stub 32 by a connection node 44A on a line connected to the positive input terminal 41A and a connection node 44B on a line connected to the negative input terminal 41B. The n·λ/4 line 33 is connected to the shunt line 34 by a connection node 46A on a line connected to a positive output terminal 49A and a connection node 46B on a line connected to a negative output terminal 40B. The n·λ/4 line 33 includes an n·λ/4 line 45A connected between the connection node 44A and the connection node 46A and an n·λ/4 line 45B between the connection node 44B and the connection node 46B.

The shunt line 34 includes a λ/2 line 48 connected between a connection node 47A on a route between the connection node 46A and the positive output terminal 49A and a connection node 47B on a route between the connection node 46B and a negative output terminal 49B. The λ/2 line and the λ/4 line are constituted by a capacitance, an inductor, a line, or the like.

As described above, in the filters 31A and 31B used according to the first embodiment, the n·λ/4 line 33 is inserted between the short stub 32 and the shunt line 34. A characteristic impedance of the short stub 32 and the shunt line 34 is lower than or equal to a half of a characteristic impedance of the differential line 30. A characteristic impedance of the n·λ/4 line 33 is at least twice as high as the characteristic impedance of the differential line 30.

An equivalent circuit related to the differential component of the filters 31A and 31B used according to the first embodiment includes a λ/4 line 43, an n·λ/4 line 45, and a λ/4 line 48I as illustrated in FIG. 8C. The λ/4 line 43 is connected between a connection node 42 on a line connected to an input terminal 41 and the ground terminal. The n·λ/4 line 45 is connected between a connection node 44 on a line connected to the input terminal 41 and a connection node 46 on a line connected to an output terminal 49. The λ/4 line 48I is connected between a connection node 47 on a line connected to the output terminal 49 and the ground terminal. The λ/4 line 43 corresponds to the λ/4 lines 43A and 43B of the short stub 32 in FIG. 8B. The n·λ/4 line 45 corresponds to the lines 45A and 45B of FIG. 8B. The λ/4 line 48I corresponds to the λ/2 line 48 in FIG. 8B. The λ/4 line 48I is grounded and is thus equivalent in that after a travel by λ/4, a reflection occurs to cause a travel by λ/2, and after a further travel by λ/4, the differential component is advanced by λ/2.

An equivalent circuit related to the common-mode component of the filters 31A and 31B used according to the first embodiment includes the λ/4 line 43, the n·λ/4 line 45, and a λ/4 line 48H as illustrated in FIG. 8D. The λ/4 line 43 and the n·λ/4 line 45 are the same as the differential component and respectively correspond to the λ/4 lines 43A and 43B and the lines 45A and 45B. The λ/4 line 48H corresponds to the λ/2 line 48 in FIG. 8B and is not grounded (is open). Thus, the λ/4 line 48H is equivalent in that after a travel by λ/4, a reflection occurs without a phase change, and after a further travel by λ/4, the common-mode component is advanced by λ/2.

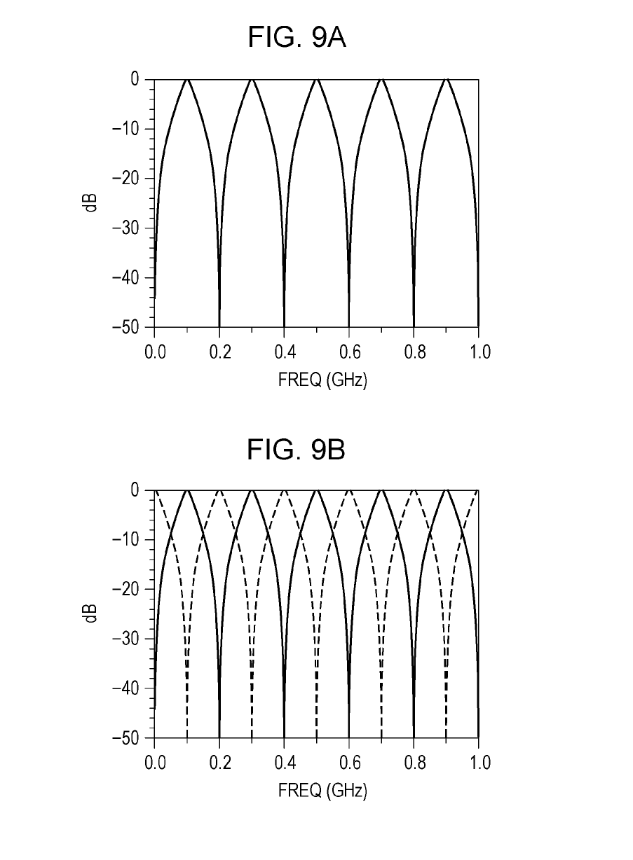

FIGS. 9A and 9B illustrate frequency characteristics of the short stub 32 and the shunt line 34 for the filters 31A and 31B used according to the first embodiment, in which FIG. 9A illustrates the frequency characteristic of the short stub 32, and FIG. 9B illustrates the frequency characteristic of the shunt line 34.

The frequency characteristics of the differential component and the common-mode component of the short stub 32 are identical to each other and are the characteristics as illustrated in FIG. 9A in a case where the differential clock signal at the frequency at 0.1 GHz is set to be transmitted. That is, with the setting of f0=0.1 GHz, the attenuation of f0(2n−1) (n: a positive integer) is low, and the attenuation of f0·2n is high. Therefore, the short stub 32 passes 0.1 GHz, 0.3 GHz, 0.5 GHz, . . . and attenuates the frequency at zero, 0.2 GHz, 0.4 GHz, 0.6 GHz, . . . . In this manner, the short stub 32 reduces the common-mode noise and the differential noise at a frequency 2n times as high as the clock frequency f0.

The frequency characteristic of the differential component of the shunt line 34 is a characteristic represented by a solid line in FIG. 9B in a case where the differential clock signal at the frequency at 0.1 GHz is set to be transmitted. That is, the attenuation of f0(2n−1) (n: a positive integer) is low, and the attenuation of f0·2n is high. Therefore, with the setting of f0=0.1 GHz, the shunt line 34 passes the differential components at 0.1 GHz, 0.3 GHz, 0.5 GHz, . . . and attenuates the differential components at the frequency at zero, 0.2 GHz, 0.4 GHz, 0.6 GHz, . . . .

The frequency characteristic of the common-mode component of the shunt line 34 is a characteristic represented by a dotted line in FIG. 9B in a case where the differential clock signal at the frequency at 0.1 GHz is set to be transmitted. That is, the attenuation of f0·2n (n: a positive integer) is low, and the attenuation of f0·(2n−1) is high. Therefore, with the setting of f0=0.1 GHz, the shunt line 34 passes the common-mode components at the frequency at zero, 0.2 GHz, 0.4 GHz, 0.6 GHz, . . . and attenuates the common-mode components at 0.1 GHz, 0.3 GHz, 0.5 GHz, . . . . In other words, a shunt circuit reduces the common-mode noise at a frequency the clock frequency f0(2n−1).

The filters are provided on both the sides of the differential line in the balanced transmission apparatus for the differential clock signal according to the first embodiment, but the length of the differential line 30 is set as λ·n/2. In other words, the two filters 31A and 31B are connected to each other by the differential line 30 having the length of λ·n/2, and accordingly, the filter characteristic degradation by the resonance generated between the two filters 31A and 31B is avoided.

Furthermore, with regard to the short stub 32 and the shunt line 34, as illustrated in FIG. 9B, since the reactance polarities are opposite in the frequency characteristic of the common-mode component, the resonance point exists. In view of the above, the n·λ/4 line 33 is inserted between the short stub 32 and the shunt line 34 in the filters 31A and 31B according to the first embodiment to set the same reactance polarity, and the resonance of the short stub 32 and the shunt line 34 is avoided. According to this, it is possible to reduce the noise of the common-mode component in a broad band region.

Here, a description will be a state in which the resonance can be avoided by inserting the n·λ/4 line 33 between the short stub 32 and the shunt line 34 with respect to the filter illustrated in FIG. 7B as in the filter illustrated in FIG. 8B according to the first embodiment.

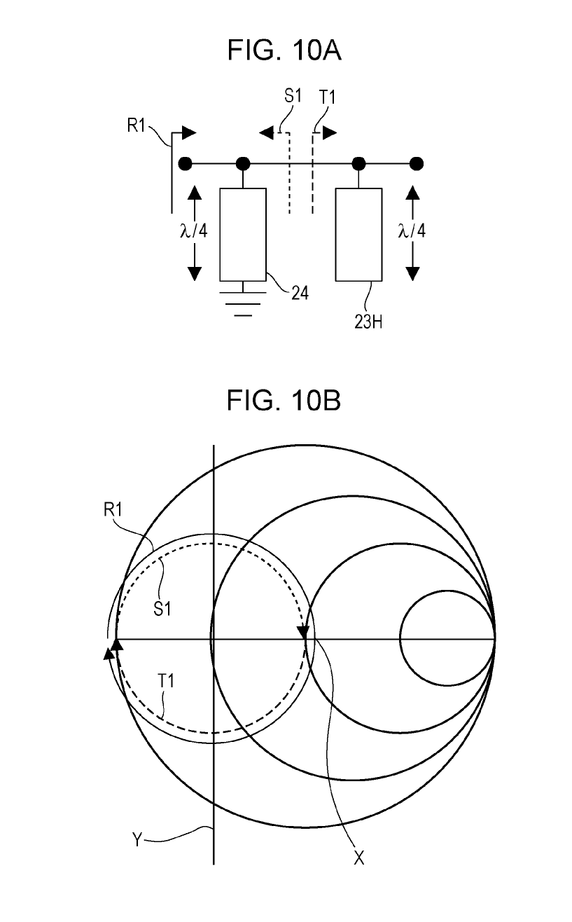

FIGS. 10A and 10B illustrate an equivalent circuit of the common-mode component in the filter illustrated in FIG. 7B and a Smith chart representing a phase relationship, in which FIG. 10A illustrates the equivalent circuit, and FIG. 10B illustrates the Smith chart.

As illustrated in FIG. 10A, this equivalent circuit includes the λ/4 line 24 connected between a connection node existing between the input terminal and the output terminal and the ground terminal and the λ/4 line 23 that is connected to the connection node existing between the input terminal and the output terminal and is not grounded (is open). A signal input from the input terminal is denoted by R1, a signal using the λ/4 line 24 as a route is denoted by S1, and a signal using the λ/4 line 23 as a route is denoted by T1.

In FIG. 10B, the signals R1, S1, and T1 respectively correspond to the above-mentioned signals, and tips of arrows represent locations at (2n−1)f0. The tip of the signal R1 is at an original zero point location, the tip of the signal S1 is at a location denoted by X, and the tip of the signal T1 is at a zero point location. The tip location of the signal S1 is a location symmetric to the tip locations of the signals R1 and T1 with respect to a straight line indicated by Y and is in a conjugate relationship to therefore realize matching for causing the common-mode component to pass through.

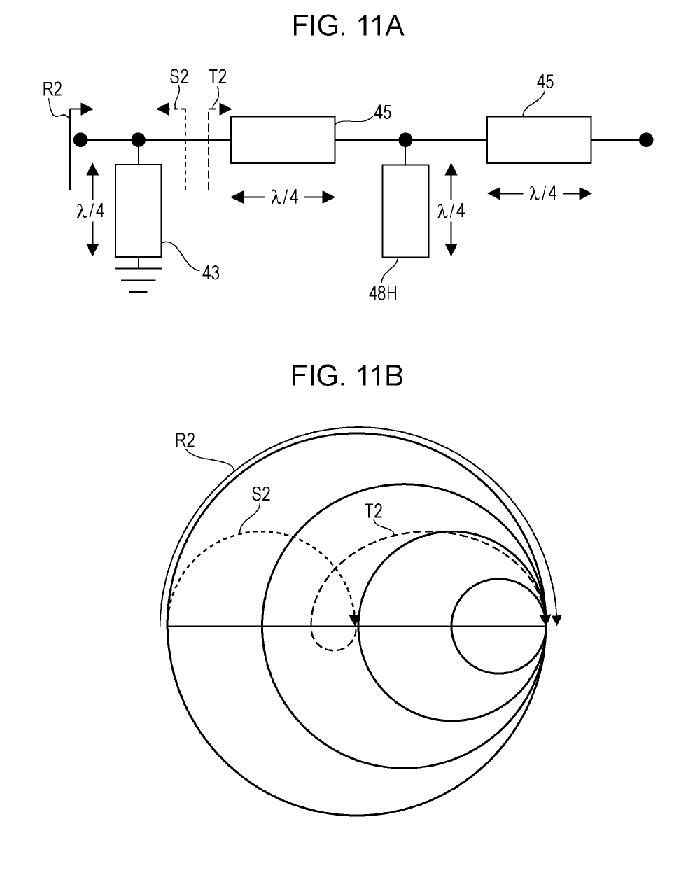

FIGS. 11A and 11B illustrate an equivalent circuit of the common-mode component in the filters according to the first embodiment illustrated in FIG. 8B and a Smith chart representing a phase relationship, in which FIG. 11A illustrates the equivalent circuit, and FIG. 11B illustrates the Smith chart.

This equivalent circuit includes connected the λ/4 line 43 between the input terminal and the ground terminal, the two λ/4 lines 45 connected in series between the input terminal and the output terminal, and the λ/4 line 48H that is connected to a connection node of the two λ/4 lines 45 and is not grounded (is open). A signal input from the input terminal is represented by R2, a signal using the λ/4 line 43 as a route is represented by S2, and a signal using the λ/4 line 45, the λ/4 line 48H, and the λ/4 line 45 as a route is represented by T2.

In FIG. 11B, the signals R2, S2, and T2 respectively correspond to the above-mentioned signals, and tips of arrows represent locations at (2n−1)f0. The tips of the signals R2, S2, and T2 are at locations on an opposite side of the zero point and are not in the conjugate relationship, so that the common-mode component does not pass through.

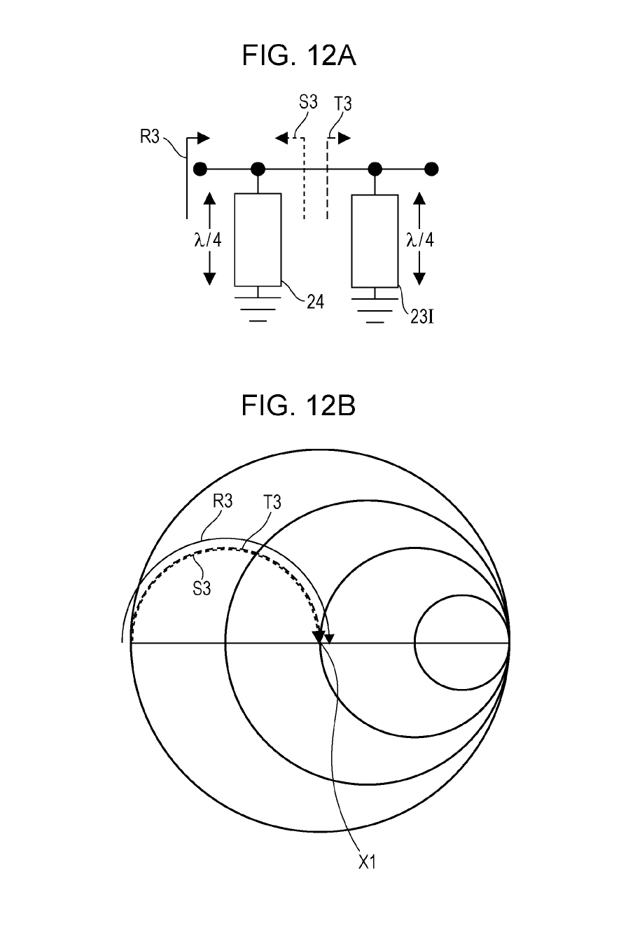

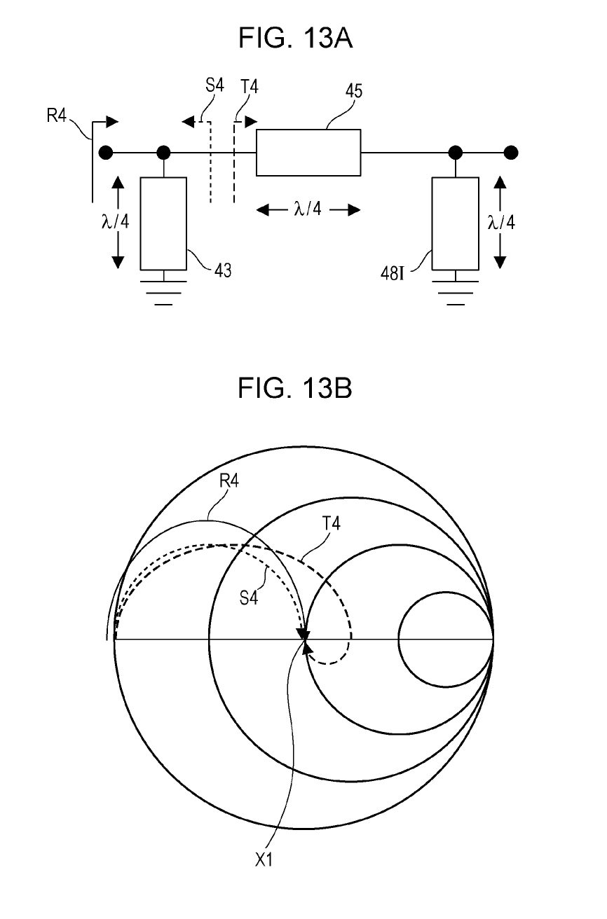

FIGS. 12A and 12B illustrate an equivalent circuit of the differential component in the filter illustrated in FIG. 7B and a Smith chart representing a phase relationship, in which FIG. 12A illustrates the equivalent circuit, and FIG. 12B illustrates the Smith chart. FIGS. 13A and 13B illustrate an equivalent circuit of the differential component in the filters according to the first embodiment illustrated in FIG. 8B and a Smith chart representing a phase relationship, in which FIG. 13A illustrates the equivalent circuit, and FIG. 13B illustrates the Smith chart. Since the described contents of FIGS. 12A and 12B and FIGS. 13A and 13B is similar to the described contents of FIGS. 10A and 10B and FIGS. 11A and 11B and may easily be understood, a description thereof will be omitted. In either case, the signals on the respective routes are at a frequency (2n−1)f0 and are in the conjugate relationship to therefore realize matching for causing the differential component to pass through.

As described above, the filters 31A and 31B used in the balanced transmission apparatus according to the first embodiment cause the differential component at a frequency (2n−1) (n: a positive integer) times as high as the basis frequency to pass through but do not cause the other differential component and the common-mode component to pass through, and an attenuation (reflection) occurs. Therefore, the balanced transmission apparatus for the differential clock signal according to the first embodiment transmits the differential components in frequencies (2n−1) (n: a positive integer) times as high as the basis frequency but does not transmit the other differential component and the common-mode component, and the transmitted differential clock signal has a rectangular wave shape.

A balanced transmission apparatus for the differential clock signal according to a second embodiment has the same circuit configuration as that of the balanced transmission apparatus according to the first embodiment illustrated in FIG. 8A, but the filters 31A and 31B are different from the filters according to the first embodiment illustrated in FIG. 8B.

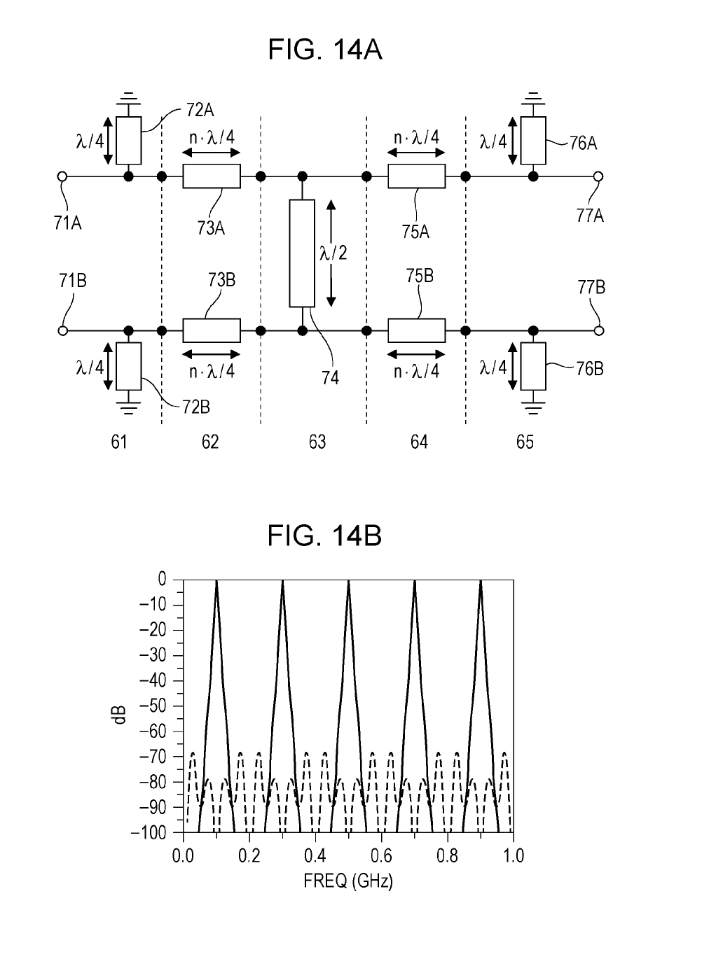

FIGS. 14A and 14B illustrate a circuit configuration of the filters 31A and 31B used in the balanced transmission apparatus for the differential clock signal according to a second embodiment and a frequency characteristic of the balanced transmission apparatus, in which FIG. 14A illustrates a circuit configuration, and FIG. 14B illustrates the frequency characteristic of the balanced transmission apparatus.

As illustrated in FIG. 14A, according to the second embodiment, the filters 31A and 31B include a first short stub 61, a first n·λ/4 line 62, a shunt line 63, a second n·λ/4 line 64, and a second short stub 65. Constitution elements of the filters 31A and 31B according to the second embodiment are the same as those according to the first embodiment, and a description thereof will be omitted.

The filters 31A and 31B according to the second embodiment has a configuration in which elements corresponding to the short stub 32 and the n·λ/4 line 33 are further provided on an output side to be symmetric with respect to the shunt line 34 in the filters 31A and 31B according to the first embodiment.

FIG. 14B illustrates the frequency characteristic the balanced transmission apparatus for the differential clock signal according to the second embodiment having the configuration illustrated in FIG. 8A where the filters illustrated in FIG. 14A are used as the filters 31A and 31B. In FIG. 14B, a solid line represents the frequency characteristic of the differential component, and a dotted line represents the frequency characteristic of the common-mode component.

As illustrated in FIG. 14B, the balanced transmission apparatus for the differential clock signal according to the second embodiment cause the differential component at a frequency (2n−1) (n: a positive integer) times as high as the basis frequency (0.1 GHz) to pass through but do not cause the other differential component and the common-mode component to pass through, and an attenuation (reflection) occurs.

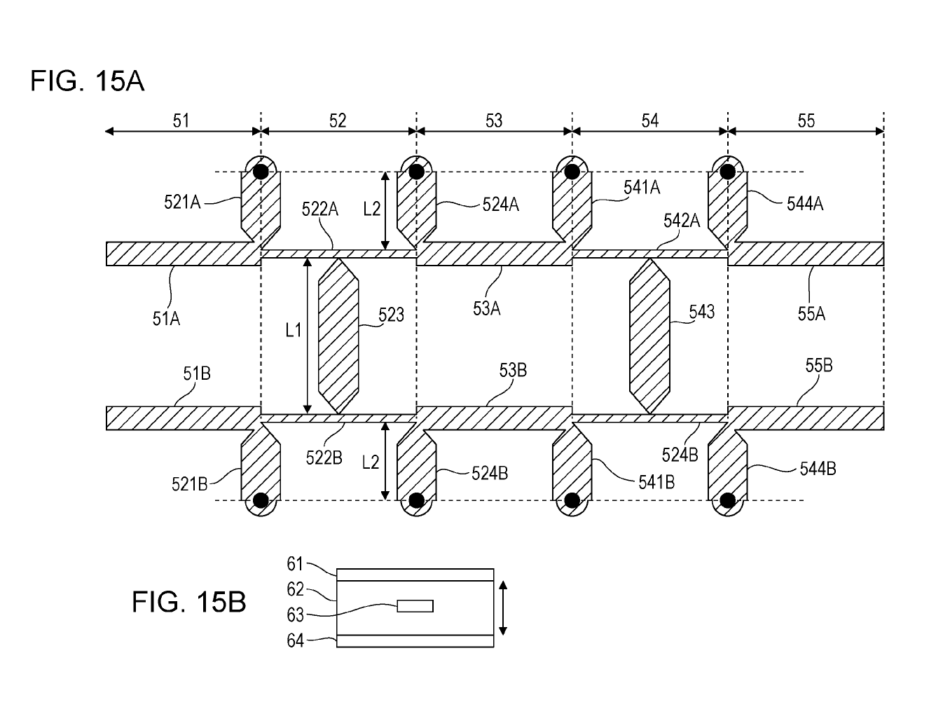

FIGS. 15A and 15B illustrate a configuration in a case where the filter 31A, the differential line 30, and the filter 31B in the balanced transmission apparatus according to the second embodiment are implemented by a balanced strip line formed on the dielectric substrate (the basis frequency 1.9 GHz), in which FIG. 15A illustrates a line pattern and FIG. 15B is a cross sectional view of the line.

As illustrated in FIG. 15B, the line includes an upper GND layer 61, a lower GND layer 64, a dielectric layer 62 formed between the upper GND layer 61 and the lower GND layer 64, and a signal layer 63 provided in the dielectric layer 62. For example, the upper GND layer 61, the lower GND layer 64, and the signal layer 63 are made of a copper layer having a thickness of 0.035 mm. The upper GND layer 61 and the lower GND layer 64 are provided across an entire substrate surface, and the signal layer 63 has a pattern as illustrated in FIG. 15A. The dielectric layer 62 is made of an FR4 having a thickness of 1 mm.

As illustrated in FIG. 15A, the signal layer 63 includes areas 51 to 55. The area 51 corresponds to a connection part where the differential clock transmitter 11 is connected to the filter 31A, and a length of the area is 70 mm. The area 51 includes two lines 51A and 51B having a width of 0.49 mm. The two lines 51A and 51B are provided in parallel with a gap at a distance L1 (70 mm). The positive signal of the differential signal is input to the line 51A, and the negative signal is input to the line 51B. Parts where the lines 51A and 51B in the area 51 are connected to the area 52 correspond to nodes 71A and 71B of FIG. 14A.

The area 52 corresponds to the part of the filter 31A illustrated in FIG. 14A. A length of the area 52 is 70 mm. The area 52 includes two lines 522A and 522B having a width of 0.1 mm. The two lines 522A and 522B are provided in parallel with a gap at the distance L1 (70 mm). Parts where the line 522A and 522B in the area 52 are connected to the area 51 correspond to the nodes 71A and 71B of FIG. 14A. Parts where the line 522A and 522B in the area 52 are connected to the area 53 correspond to nodes 77A and 77B of FIG. 14A.

The area 52 includes two lines 521A and 521B that are connected between the line 522A and 522B and a ground line at a border with the area 51 and that have a width of λ mm and a length L2 (35 mm). The two lines 521A and 521B correspond to the λ/4 lines 72A and 72B of FIG. 14A. Furthermore, the area 52 includes two lines 524A and 524B that are connected between the line 522A and 522B and the ground line at a border with the area 53 and that have a width of λ mm and the length L2 (35 mm). The two lines 524A and 524B correspond to λ/4 line 76A and 76B of FIG. 14A.

The area 52 also includes a line 523 that connects between a midpoint of the line 522A and a midpoint of the line 522B and that has a width of λ mm and the length L1. The line 523 corresponds to a λ/2 line 74 in FIG. 14A. A section between a connection part of the line 522A to the area 51 and a connection part to the line 523 corresponds to an n·λ/4 line 73A of FIG. 14A. A section between a connection part of the line 522B to the area 51 and a connection part to the line 523 corresponds to an n·λ/4 line 73B of FIG. 14A. A section between a connection part of the line 522A to the area 51 and a connection part to the line 523 corresponds to an n·λ/4 line 75A of FIG. 14A. A section between a connection part of the line 522B to the area 53 and a connection part to the line 523 corresponds to an n·λ/4 line 75B of FIG. 14A.

The area 53 corresponds to a part of the differential line 30, and a length of the area 53 is 70 mm (n=1). The area 53 includes two lines 53A and 53B having a width of 0.49 mm. Parts where the lines 53A and 53B of the area 53 are connected to the area 52 correspond to nodes 77A and 77B of FIG. 14A. Parts where the lines 53A and 53B of the area 53 are connected to the area 54 correspond to the nodes 71A and 71B in a case where the area 54 is implemented by the filters of FIG. 14A.

The area 54 corresponds to a part of the filter 31B illustrated in FIG. 14A and is implemented by the filter of FIG. 14A. Since the area 54 is similar to the area 52, a description thereof will be omitted.

The area 55 corresponds to a connection part of the filter 31B to the differential clock receiver 13, and a length of the area 55 is 70 mm. Since the area 55 is similar to the area 51, a description thereof will be omitted.

In FIG. 15, the example of the filter implemented by the balanced strip line has been illustrated, but the filter can of course be implemented by using the reactance elements such as the balanced strip line, the inductor, and the capacitance in combinations.

A balanced transmission apparatus for the differential clock signal according to a third embodiment has the same circuit configuration as that of the balanced transmission apparatus according to the first embodiment illustrated in FIG. 8A, but the filters 31A and 31B are different from the filters according to the first embodiment illustrated in FIG. 8B.

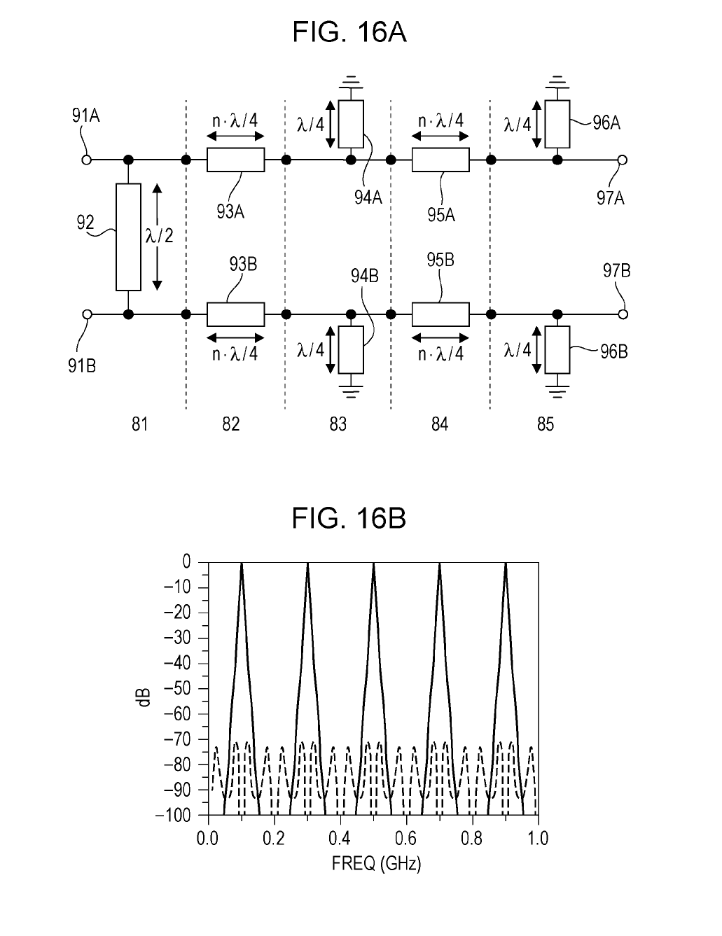

FIGS. 16A and 16B illustrate a circuit configuration of the filters 31A and 31B used in the balanced transmission apparatus for the differential clock signal according to the third embodiment and a frequency characteristic of the balanced transmission apparatus, in which FIG. 16A illustrates a circuit configuration, and FIG. 16B illustrates the frequency characteristic of the balanced transmission apparatus.

As illustrated in FIG. 16A, according to the third embodiment, the filters 31A and 31B include a first shunt line 81, a first n·λ/4 line 82, a short stub 83, a second 2n·λ/4 line 84, and a second shunt line 85. Constitution elements of the filters 31A and 31B according to the third embodiment are the same as those according to the first embodiment, and a description thereof will be omitted.

FIG. 16B illustrates the frequency characteristic of the balanced transmission apparatus for the differential clock signal according to the third embodiment which has a configuration illustrated in FIG. 8A and uses the filters illustrated in FIG. 14A as the filters 31A and 31B. In FIG. 16B, a solid line represents the frequency characteristic of the differential component, and a dotted line represents the frequency characteristic of the common-mode component.

As illustrated in FIG. 16B, the balanced transmission apparatus for the differential clock signal according to the third embodiment passes through the differential component at a frequency (2n−1) (n: a positive integer) times as high as the basis frequency (0.1 GHz) but the other differential component and the common-mode component do not pass through, and an attenuation (reflection) occurs.

The balanced transmission apparatus for the differential clock signal according to a fourth embodiment has the same circuit configuration as that of the balanced transmission apparatus according to the first embodiment illustrated in FIG. 8A, but the filters 31A and 31B are different from the filters according to the first embodiment illustrated in FIG. 8B.

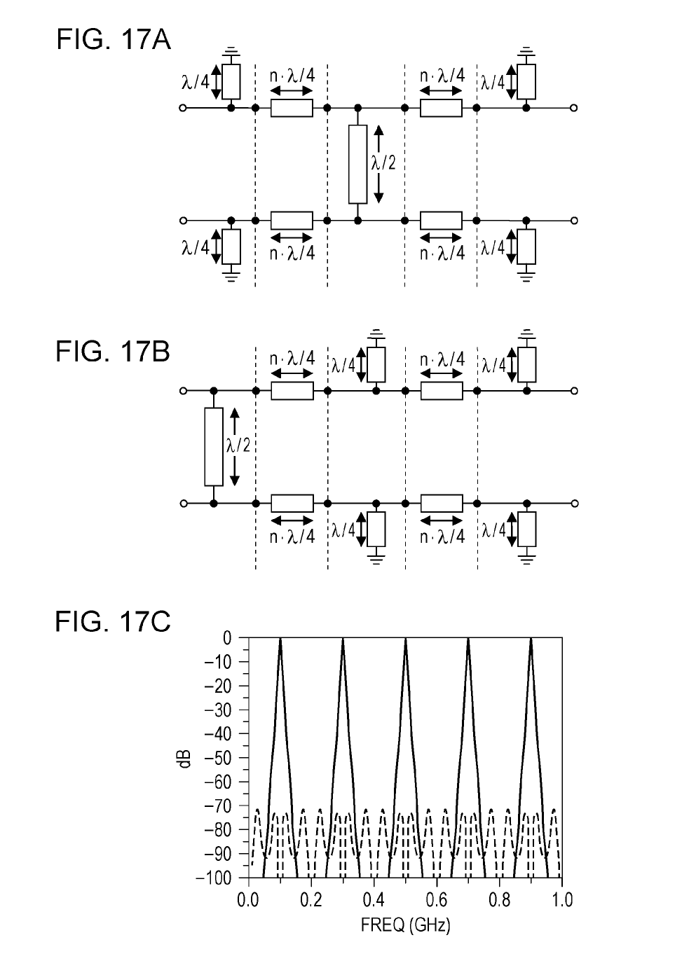

FIGS. 17A, 17B, and 17C illustrate circuit configurations of the filters 31A and 31B used in the balanced transmission apparatus for the differential clock signal according to the fourth embodiment and a frequency characteristic of the balanced transmission apparatus in which FIG. 17A illustrates the circuit configuration of the filter 31A, FIG. 17B illustrates the circuit configuration of the filter 31B, and FIG. 17C illustrates the frequency characteristic of the balanced transmission apparatus.

As illustrated in FIG. 17A, according to the fourth embodiment, the filter 31A has the same configuration as the filter according to the second embodiment illustrated in FIG. 14A. As illustrated in FIG. 17B, the filter 31B has the same configuration as the filter according to the third embodiment illustrated in FIG. 16A.

FIG. 17C illustrates the frequency characteristic of the balanced transmission apparatus for the differential clock signal according to the fourth embodiment which has a configuration illustrated in FIG. 8A and uses the filters illustrated in FIGS. 17A and 17B as the filters 31A and 31B, respectively. In FIG. 17C, a solid line represents the frequency characteristic of the differential component, and a dotted line represents the frequency characteristic of the common-mode component.

As illustrated in FIG. 17C, the balanced transmission apparatus for the differential clock signal according to the fourth embodiment passes the differential component at a frequency (2n−1) (n: a positive integer) times as high as the basis frequency (0.1 GHz) but does not pass the other differential component and the common-mode component, and an attenuation (reflection) occurs.

According to the fourth embodiment, the filter 31A may include the same configuration as the filter according to the third embodiment illustrated in FIG. 16A, and the filter 31B may include the same configuration as the filter according to the second embodiment illustrated in FIG. 14A.

As described above, the filters 31A and 31B of the balanced transmission apparatus for the differential clock signal according to the first to fourth embodiments are constituted by the reactance elements, so that the filters 31A and 31B can be miniaturized, and a higher frequency can also easily be obtained.

The balanced transmission apparatus for the differential clock signal according to the first to fourth embodiments passes the differential component at a frequency (2n−1) (n: a positive integer) times as high as the basis frequency (0.1 GHz) but does not pass the other differential component and the common-mode component, an attenuation (reflection) occurs. For that reason, the balanced transmission apparatus for the differential clock signal according to the first embodiment transmits the differential component at a frequency (2n−1) (n: a positive integer) times as high as the basis frequency but does not transmit the other differential component and the common-mode component. Therefore, the influence of the noise is hardly received, and the transmitted differential clock signal is reproduced so as to have the rectangular wave shape.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A transmission apparatus, comprising:
a transmission circuit configured to output a differential signal;
a first filter configured to filter the differential signal output by the transmission circuit;
a differential line that is configured to transmit the differential signal filtered by the first filter and has a length of m·λ/2 (m: a positive integer, λ: an electrical length corresponding to a basis frequency of the differential signal);
a second filter configured to filter the differential signal transmitted on the differential line; and
a reception circuit to which the differential signal filtered by the second filter is input,
wherein the first filter and the second filter are each constituted by a reactance element, and
wherein impedance matching is implemented with respect to a differential component of the differential signal at a frequency (2n−1) (n: a positive integer) times as high as the basis frequency, and impedance mismatching is caused with respect to a differential component of the differential signal at a frequency other than the frequency (2n−1) (n: a positive integer) times as high as the basis frequency and a common-mode component of the differential signal.

2. The transmission apparatus according to claim 1,
wherein the differential signal is a differential clock signal.

3. The transmission apparatus according to claim 1,
wherein the first filter and the second filter include a shunt line, a short stub, and a λ/4 electrical length line.

4. The transmission apparatus according to claim 3,
wherein the first filter and the second filter further include
a shunt circuit including a λ/4 electrical length line connected between differential signal lines,
a short stub including two λ/4 electrical length lines that respectively ground the differential signal lines; and
a λ/4 electrical length line including two p·λ/4 (p: a positive integer) electrical length lines respectively connected between the differential signal lines of the shunt circuit and the differential signal lines of the short stub.

5. The transmission apparatus according to claim 3,
wherein the first filter and the second filter further include
a shunt circuit including a λ/4 electrical length line connected between differential signal lines,
first and second λ/4 electrical length lines including two p·λ/4 (p: a positive integer) electrical length lines which are arranged on both sides of the shunt circuit and are respectively connected between the differential signal lines,
a first short stub that is arranged on a side opposite to the shunt circuit on the first λ/4 electrical length line and includes two λ/4 electrical length lines that respectively ground the differential signal lines, and
a second short stub that is arranged on a side opposite to the shunt circuit on the second λ/4 electrical length line and includes two λ/4 electrical length lines that respectively ground the differential signal lines.

6. The transmission apparatus according to claim 3,
wherein the first filter and the second filter further include
a first short stub including two λ/4 electrical length lines that respectively ground the differential signal lines,
first and second λ/4 electrical length lines including two p·λ/4 (p: a positive integer) electrical length lines which are arranged on both sides of the first short stub and are respectively connected between the differential signal lines,
a shunt circuit that is arranged on a side opposite to the first short stub on the first λ/4 electrical length line and includes a λ/4 electrical length line connected between differential signal lines, and
a second short stub that is arranged on a side opposite to the first short stub on the second λ/4 electrical length line and includes two λ/4 electrical length lines that respectively ground the differential signal lines.

7. The transmission apparatus according to claim 3,
wherein the first filter further includes
a shunt circuit including a λ/4 electrical length line connected between differential signal lines,
first and second λ/4 electrical length lines including two p·λ/4 (p: a positive integer) electrical length lines which are arranged on both sides of the shunt circuit and are respectively connected between the differential signal lines,
a first short stub that is arranged on a side opposite to the shunt circuit on the first λ/4 electrical length line and includes two λ/4 electrical length lines that respectively ground the differential signal lines, and
a second short stub that is arranged on a side opposite to the shunt circuit on the second λ/4 electrical length line and includes two λ/4 electrical length lines that respectively ground the differential signal lines, and
wherein the second filter further includes
a first short stub including two λ/4 electrical length lines that respectively ground the differential signal lines,
first and second λ/4 electrical length lines including two p·λ/4 (p: a positive integer) electrical length lines which are arranged on both sides of the first short stub and are respectively connected between the differential signal lines,
a shunt circuit that is arranged on a side opposite to the first short stub on the first λ/4 electrical length line and includes two λ/4 electrical length line connected between differential signal lines, and
a second short stub that is arranged on a side opposite to the first short stub on the second λ/4 electrical length line and includes two λ/4 electrical length lines that respectively ground the differential signal lines.

8. A high frequency filter, comprising:
a reactance element,
wherein impedance matching is implemented with respect to a differential component of a differential signal at a frequency (2n−1) (n: a positive integer) times as high as a basis frequency, and impedance mismatching is caused with respect to a differential component of the differential signal at a frequency other than the frequency (2n−1) (n: a positive integer) times as high as the basis frequency and a common-mode component of the differential signal.

9. The high frequency filter according to claim 8, further comprising:
a filter for a differential clock signal.

10. The high frequency filter according to claim 8, further comprising:
a shunt line;
a short stub; and
a λ/4 electrical length line.

11. The high frequency filter according to claim 10, further comprising:
a shunt circuit including a λ/4 electrical length line connected between differential signal lines;
a short stub including two λ/4 electrical length lines that respectively ground the differential signal lines; and
a λ/4 electrical length line including two p·λ/4 (p: a positive integer) electrical length lines respectively connected between the differential signal lines of the shunt circuit and the differential signal lines of the short stub.

12. The high frequency filter according to claim 10, further comprising:
a shunt circuit including a λ/4 electrical length line connected between differential signal lines;
first and second λ/4 electrical length lines including two p·λ/4 (p: a positive integer) electrical length lines which are arranged on both sides of the shunt circuit and are respectively connected between the differential signal lines;
a first short stub that is arranged on a side opposite to the shunt circuit on the first λ/4 electrical length line and includes two λ/4 electrical length lines that respectively ground the differential signal lines; and
a second short stub that is arranged on a side opposite to the shunt circuit on the second λ/4 electrical length line and includes two λ/4 electrical length lines that respectively ground the differential signal lines.

13. The high frequency filter according to claim 10, further comprising:
a first short stub including two λ/4 electrical length lines that respectively ground the differential signal lines;
first and second λ/4 electrical length lines including two p·λ/4 (p: a positive integer) electrical length lines which are arranged on both sides of the first short stub and are respectively connected between the differential signal lines;
a shunt circuit that is arranged on a side opposite to the first short stub on the first λ/4 electrical length line and includes a λ/4 electrical length line connected between the differential signal lines; and
a second short stub that is arranged on a side opposite to the first short stub on the second λ/4 electrical length line and includes two λ/4 electrical length lines that respectively ground the differential signal lines.
